(19) United States
(12) Patent Application Publication
(10) Pub. No.: US 2017/0250369 A1
(43) Pub. Date: Aug. 31, 2017

(54) METHOD FOR MANUFACTURING DISPLAY DEVICE AND DISPLAY DEVICE

(71) Applicant: Japan Display Inc., Minato-ku (JP)

(72) Inventor: Akinori KAMIYA, Minato-ku (JP)

(73) Assignee: Japan Display Inc., Minato-ku (JP)

(21) Appl. No.: 15/438,919

(22) Filed: Feb. 22, 2017

(30) Foreign Application Priority Data
Feb. 29, 2016 (JP) 2016-037310

(51) Int. Cl. H01L 51/52; H01L 51/56; H01L 27/32

(52) U.S. Cl. CPC H01L 51/5246; H01L 27/3244; H01L 51/56; H01L 2227/323

(57) ABSTRACT

A method for manufacturing a display device includes steps of preparing an insulating substrate; forming a circuit layer on the insulating substrate; forming a light emitting element layer on the circuit layer in the display area; forming a sealing layer on the circuit layer in the terminal area and on the light emitting element layer in the display area; applying resin material onto the sealing layer in the terminal area and the display area; forming an applied resin layer so as to cover the display area and so as to expose the sealing layer in the terminal area by curing the resin material applied; and removing a part of the sealing layer, formed in the terminal area, using the applied resin layer as a mask.

### CROSS-REFERENCE TO RELATED APPLICATION

The present application claims priority from Japanese application JP2016-037310 filed on Feb. 29, 2016, the content of which is hereby incorporated by reference into this application.

### BACKGROUND OF THE INVENTION

1. Field of the Invention

The present invention relates to a method for manufacturing a display device and a display device.

2. Description of the Related Art

Conventionally, as a display device, there has been known a display device that includes a TFT (thin film transistor) substrate including a circuit layer including a thin film transistor, etc., an organic EL (Electro Luminescence) element layer formed on the circuit layer, and a sealing layer formed on the organic EL element layer by laminating resin or inorganic material. For example, JP 2004-139977 A discloses a sealing layer formed by laminating a photo-curable resin layer formed on an organic EL layer and an inorganic film made from silicon nitride formed on the photo-curable resin layer (see paragraph 0005 etc., in the specification of JP 2004-139977 A).

As the above described display device, there has been known a display device including a protection film formed opposing to a TFT substrate. As a protection film needs to be adhered to a TFT substrate by adhesive agent, it is possible that foreign matter is mixed between the protection film and the TFT substrate when adhering. As a result, it is possible that the sealing layer of the TFT substrate is damaged.

As a TFT substrate, there has been known a TFT substrate including a display area for image display and a terminal area around the display area with a terminal arranged therein. In the terminal area, it is necessary to implement so-called terminal exposure for exposing a terminal to ensure electric connection to an electronic component, etc., outside the TFT substrate. For this purpose, in a process for manufacturing a display device, a sealing layer is initially formed over the entire surface of a TFT substrate including the terminal area, and a part of the sealing layer formed in the terminal area is thereafter removed by means of dry etching etc., using a protection film as a mask, whereby the terminal is exposed outside. However, when a protection film is used as a mask, it is possible that the sealing film is damaged, and that the film becomes cloudy due to the gas for dry etching, which may possibly affect image display.

### SUMMARY OF THE INVENTION

An object of the present invention is to prevent a sealing layer from being damaged due to mixture of foreign matter or to expose a terminal without affecting image display.

A method for manufacturing a display device according to one aspect of the present invention is a method for manufacturing a display device including a display area for image display, and a terminal area around the display area with a terminal arranged therein, including steps of preparing an insulating substrate; forming a circuit layer having the terminal on the insulating substrate; forming a light emitting element layer on the circuit layer in the display area; forming a sealing layer on the circuit layer in the terminal area and on the light emitting element layer in the display area; applying resin material onto the sealing layer in the terminal area and the display area; forming an applied resin layer so as to cover the display area and so as to expose the sealing layer in the terminal area by curing the resin material applied; and removing a part of the sealing layer, formed in the terminal area, using the applied resin layer as a mask.

A display device according to another aspect of the present invention is a display device including a display area for image display and a terminal area around the display area with a terminal arranged therein, including a circuit layer having the terminal; a light emitting element layer formed on the circuit layer in the display area; a sealing layer formed on the light emitting element layer in the display area; and an applied resin layer made from thermosetting or UV curable resin material and formed on the sealing layer in the display area.

### BRIEF DESCRIPTION OF THE DRAWINGS

FIG. 1 is a perspective view showing an external appearance of a display device according to this embodiment;

FIG. 2 is a schematic cross sectional view schematically showing a cross section of a display device according to this embodiment;

FIG. 3 is a circuit diagram showing a circuit formed in each unit pixel;

FIG. 4 is a flowchart showing a manufacturing process of a display device according to this embodiment;

FIG. 5 is a cross sectional view explaining a manufacturing process of a display device according to this embodiment;

FIG. 6 is a cross sectional view explaining a manufacturing process of a display device according to this embodiment;

FIG. 7 is a cross sectional view explaining a manufacturing process of a display device according to this embodiment;

FIG. 8 is a plan view showing a large substrate before being cut; and

FIG. 9 is a flowchart showing a manufacturing process of a display device according to this embodiment in which respective layers are laminated on a large substrate, and the large substrate is thereafter cut, whereby a display device is obtained.

### DETAILED DESCRIPTION OF THE INVENTION

In the following, an embodiment of the present invention (hereinafter referred to as this embodiment) will be described referring to the drawings.

In this embodiment, in expressing an aspect in which a structure is placed “on the top of” another structure, a simple description of “on” includes both of a case in which one structure is placed directly on another structure such that the structures are in contact to each other and a case in which one structure is placed via a third structure above another structure, unless otherwise stated.

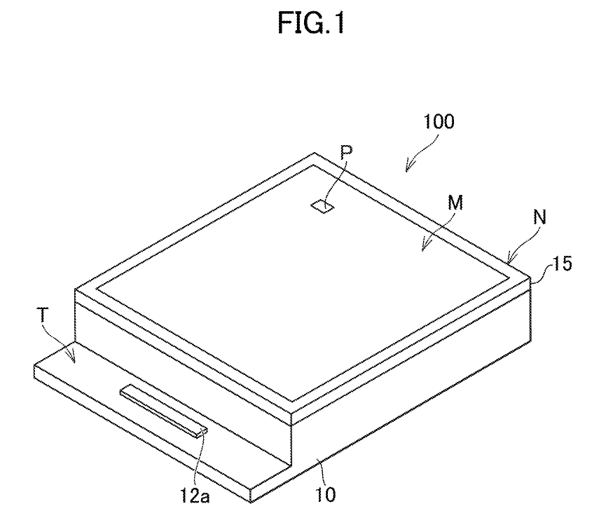

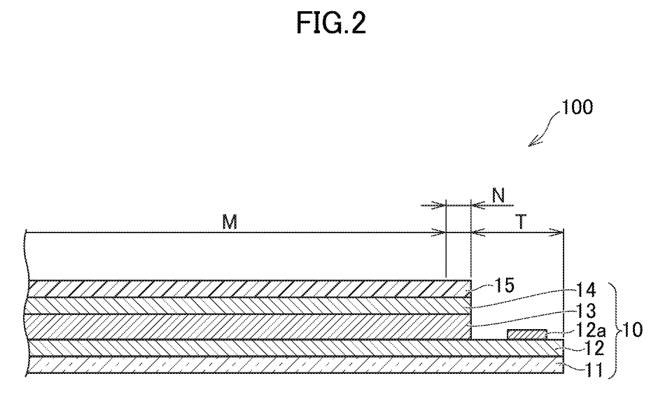

Initially, referring to FIGS. 1 and 2, a complete structure of a display device according to this embodiment will be described. FIG. 1 is a perspective view showing an external appearance of a display device according to this embodiment. FIG. 2 is a schematic cross sectional view schematically showing a cross section of a display device according to this embodiment. Although a so-called organic EL display device using an organic EL element will be described as a display device 100 in this embodiment, this is not an exclusive example, and any display device having a light emitting layer is applicable.

As shown in FIG. 1, the display device 100 includes a TFT substrate 10 having a thin film transistor etc., and an applied resin layer 15 formed on the TFT substrate 10. Further, the TFT substrate 10 has a display area M for image display and a frame area N around the display area M. Still further, the TFT substrate 10 has a terminal area T where a terminal 12a for electric connection to an electronic component etc., outside the TFT substrate 10 is formed. In the display area M, a plurality of unit pixels P are formed. Note that although only one unit pixel P is shown in FIG. 1, in actuality, a plurality of unit pixels P are arranged in a matrix in the display area M.

Note that in this embodiment the display area M is defined as an area for image display, including the entire area in the thickness direction of the TFT substrate 10 and the applied resin layer 15. That is, the display area M includes respective layers and substrates laminated in the thickness direction of the TFT substrate 10 and the applied resin layer 15. Further, the frame area N is defined as an area around the display area M, including the entire area in the thickness direction of the TFT substrate 10 and the applied resin layer 15. Still further, the terminal area T is defined as an area including at least the terminal 12a, including the entire area in the thickness direction of the TFT substrate 10.

As shown in FIG. 2, the TFT substrate 10 includes an insulating substrate 11, a circuit layer 12 formed on the insulating substrate 11, alight emitting element layer 13 formed on the circuit layer 12, and a sealing layer 14 formed on the light emitting element layer 13.

Below, details of the respective layers and substrates of the TFT substrate 10 will be described. In this embodiment, a glass substrate is used as the insulating substrate 11. However, the glass substrate may be removed in view of flexibility of a display device after formation of the respective layers and substrates thereon. That is, the insulating substrate 11 may be used as a pedestal for lamination in a manufacturing process, but may not be included in the complete display device 100. Use of a glass substrate as the insulating substrate 11 as a pedestal for lamination facilitates and stabilizes lamination of respective layers and substrates. Note that details of the manufacturing process of the display device 100 will be described later. Also note that the insulating substrate 11 is not limited to the above describe example, and a substrate made from flexible polyimide, etc., may be used in view of flexibility of a display device.

The circuit layer 12 is formed on the insulating substrate 11, and has the terminal 12a in the terminal area T. An electronic component outside the TFT substrate 10 is electrically connected to the terminal 12a. For example, a flexible printed circuit (FPC), etc., for controlling image display in the display area M is electrically connected to the terminal 12a.

The light emitting element layer 13 is a layer including an organic EL layer in which brightness is controlled in each of a plurality of unit pixels P constituting an image. The light emitting element layer 13 is formed on the circuit layer 12 at least in the display area M. The light emitting element layer 13 is a layer including an organic EL layer, a lower electrode formed on a lower side of the organic EL layer, and an upper electrode formed on an upper side of the organic EL layer, with details thereof not described. The organic EL layer includes a charge transport layer, a charge injection layer, a light emitting layer, etc.

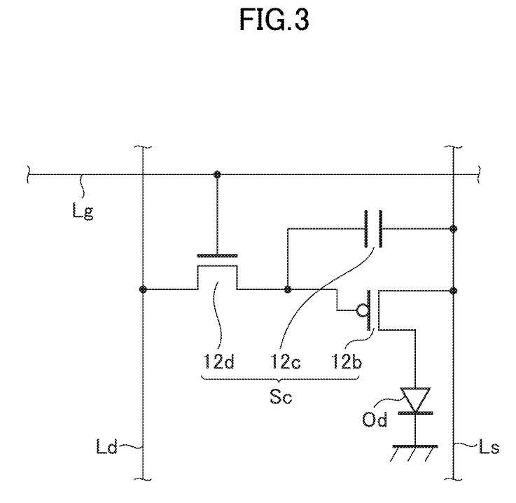

Below, with reference to FIG. 3, the light emitting principle of the light emitting element layer 13 will be described. FIG. 3 is a circuit diagram showing a circuit formed in each unit pixel P. As shown in FIG. 3, the wiring of the circuit layer 12 includes a scan line Lg, a video signal line Ld orthogonal to the scan line Lg, and a power supply line Ls. In each unit pixel P of the circuit layer 12, a pixel control circuit Sc is formed, and connected to the lower electrode of the light emitting element layer 13 through a contact hole (not shown). The pixel control circuit Sc includes a thin film transistor and a capacitor, and controls current supply to an organic light emitting diode Od formed in each unit pixel P. Note that the organic light emitting diode Od is included in the light emitting element layer 13.

As shown in FIG. 3, the pixel control circuit Sc includes a drive TFT 12b, a holding capacitor 12c, and a switching TFT 12d. A gate of the switching TFT 12d is connected to the scan line Lg. One of the source and drain of the switching TFT 12d is connected to the video signal line Ld, and the other is connected to the gates of the holding capacitor 12c and the drive TFT 12b. The source of the drive TFT 12b is connected to the power supply line Ls, and the drain of the same is connected to the organic light emitting diode Od. With a gate voltage applied to the scan line Lg, the switching TFT 12d is turned on. When a video signal is then supplied from the video signal line Ld, a charge is accumulated in the holding capacitor 12c. With charges accumulated in the holding capacitor 12c, the drive TFT 12b is turned on, and a current flows from the power supply line Ls to the organic light emitting diode Od, which then emits light.

Note that the pixel control circuit Sc may be any circuit for controlling current supply to the organic light emitting diode Od, and is not limited to the circuit shown in FIG. 3. For example, the pixel control circuit Sc may include an auxiliary capacitor for an increased capacity, besides the holding capacitor 12c, and the polarity of a transistor constituting the circuit is not limited to the one shown in FIG. 3.

Note that in this embodiment, a separately coloring method for coloring the organic EL layer so as to emit light in color in accordance with the color of each unit pixel P may be employed, or a color filter method in which all unit pixels emit light in the same color (for example, white) and only light with a predetermined wavelength is transmitted via a color filter in each unit pixel P may be employed.

Further, returning to FIG. 2, the description will continue. The sealing layer 14 is provided to prevent invasion of water from outside into the display device 100 and further to the light emitting element layer 13, and includes at least a layer made from inorganic material. As inorganic material, for example, silicon nitride, etc., may be used. The sealing layer 14 is formed on the light emitting element layer 13 in the display area M. If the sealing layer 14 is formed covering the terminal 12a, it is not possible to have the terminal 12a electrically connected to an outside electronic component. Therefore, the sealing layer 14 is formed in an area other than the terminal area T.

The applied resin layer 15 is formed on the sealing layer 14 in the display area M. In this embodiment, as the applied resin layer 15, UV curable resin material is used. Specifically, acrylic resin is used. However, this is not an exclusive example, and epoxy resin, etc., may be used. Also, the applied resin layer 15 may be made from any liquid resin material applied and then cured. For example, the applied resin layer 15 may be made from thermosetting resin material.

As described above, in the display device 100 according to this embodiment, the applied resin layer 15 is formed on the sealing layer 14 (the TFT substrate 10) in the display area M. The applied resin layer 15 protects the sealing layer 14. In the case where a protection film is formed on the applied resin layer 15 by adhering using an adhesive agent, it is possible that foreign matter is mixed between the sealing layer 14 and the film and that the sealing layer 14 may be damaged. This embodiment is free from such a problem. Also, the applied resin layer 15 is advantageous in that the applied resin layer 15 is thin and costs less, compared to a protection film.

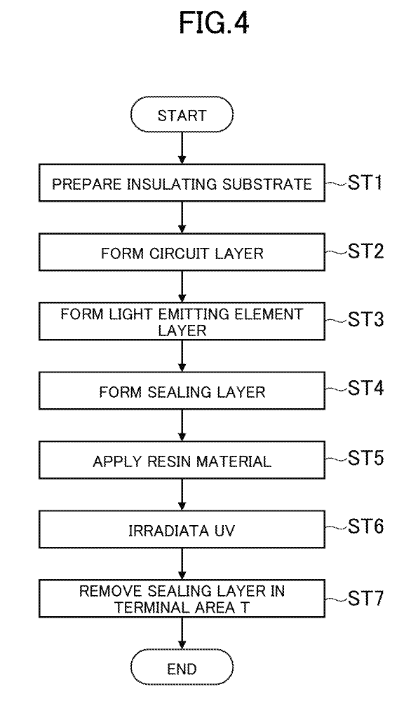

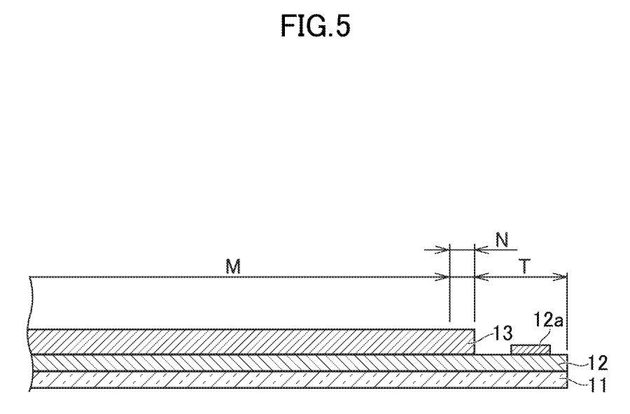

In the following, with reference to FIGS. 4 to 7, a method for manufacturing a display device according to this embodiment will be described. FIG. 4 is a flowchart showing a manufacturing process of a display device according to this embodiment. FIGS. 5 to 7 are cross sectional views explaining a manufacturing process of a display device according to this embodiment.

Initially, the insulating substrate 11 is prepared (step ST1). Then, the circuit layer 12 and the terminal 12a are formed on the insulating substrate 11 (step ST2). Further, the light emitting element layer 13 is formed on the circuit layer 12 in the display area M (step ST3). FIG. 5 shows a state with the steps up to step ST3 completed.

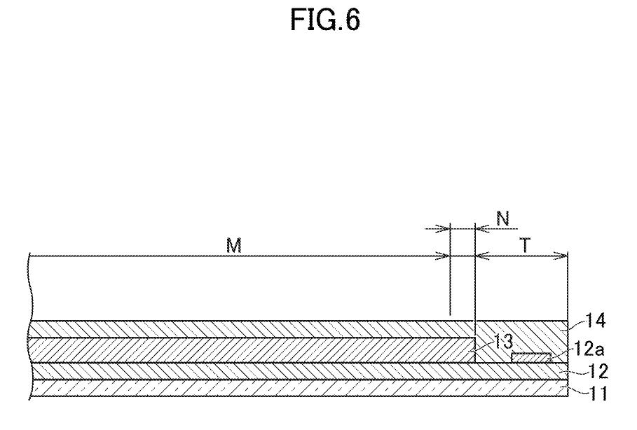

Further, the sealing layer 14 is formed on the circuit layer and the light emitting element layer 13 (step ST4). Specifically, the sealing layer 14 is formed on the circuit layer 12 in the terminal area T, and on the light emitting element layer 13 in the display area M. The sealing layer 14 may be formed by means of chemical vapor deposition (hereinafter referred to as a CVD method). As a CVD method, plasma CVD method for plasmatizing source gas to generate chemical reaction may be employed. Note that a method for forming the sealing layer 14 is not limited to the DVD method, and any other methods, including a sputtering method, an ALD (Atomic Layer Deposition) method, etc., may be used. FIG. 6 shows a state with the steps up to step ST4 completed.

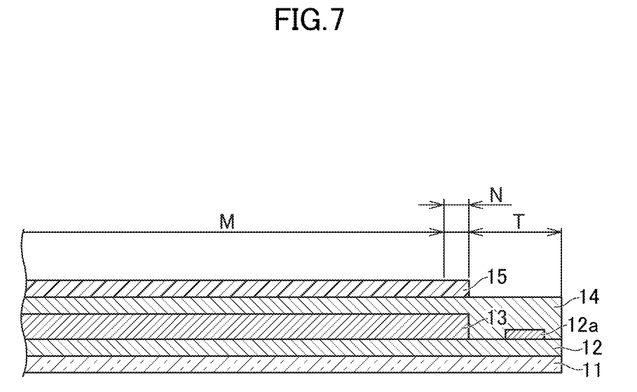

Further, acrylic resin, or liquid resin material, is applied onto the sealing layer 14 (step ST5). Further, ultraviolet light is irradiated to the acrylic resin applied to thereby cure the acrylic resin in the display area M to form the applied resin layer 15 (step ST6). In the terminal area T, the acrylic resin is removed after application so as not to be cured. As a result, the sealing layer 14 is left exposed. FIG. 7 shows a state with the steps up to step ST6 completed. Note that for formation of the applied resin layer 15, various methods, for example, ink-jet method, gravure print, flexographic print, offset print, screen print, etc., can be employed.

Further, a part of the sealing layer 14 formed in the terminal area T is removed by means of dry etching, using the applied resin layer 15 as a mask (step ST7). With the above, so called terminal exposure, or exposing the terminal 12a in the terminal area T, is implemented. With the above, the terminal 12a is available for electric connection to an outside electronic component, etc., of the TFT substrate 10. With the steps up to step ST7 completed, manufacturing of the display device 100 is completed, with the state shown in FIG. 2 resulted.

Note that in dry etching, it is possible that the applied resin layer 15 becomes cloudy. In this case, only the cloudy part of the applied resin layer 15 may be removed by means of ashing. Also, in the case where the strength of the display device 100 with the insulating substrate 11, the circuit layer 12, the light emitting element layer 13, and the sealing layer 14 is sufficient, not only a cloudy part but also the entire applied resin layer 15 may be removed by means of ashing after using the applied resin layer 15 as a mask in dry etching at step ST 7. Note that in the case where acrylic resin is used as resin material of the applied resin layer 15, ashing may be applied using gas containing oxygen or nitric oxide, for example, to remove the applied resin layer 15.

As described above, in this embodiment, the applied resin layer 15 is used as a mask in dry etching for terminal exposure. The applied resin layer 15 is thin and easy to be removed in ashing. Therefore, even if the applied resin layer 15 becomes cloudy in dry etching, image display is not affected once the cloudy part is removed.

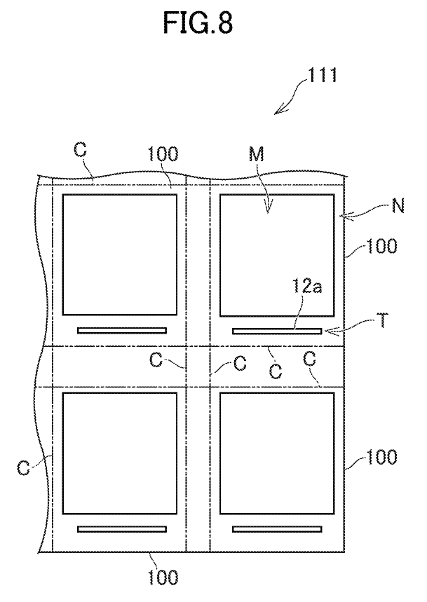

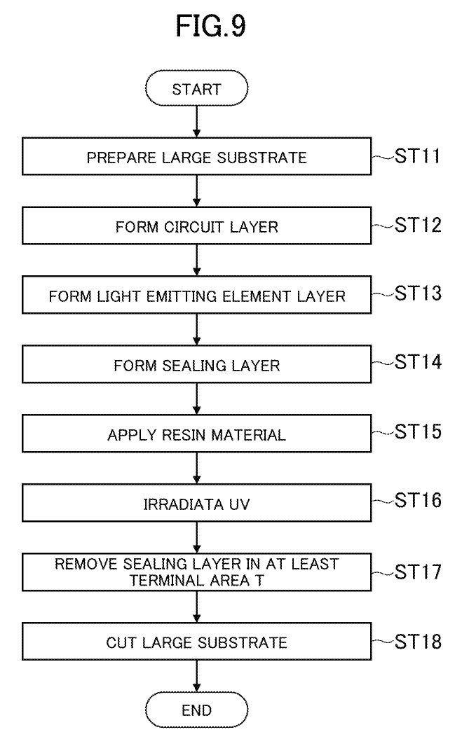

Referring to FIGS. 4 to 7, an example of manufacturing the display device 100 by laminating respective layers on an insulating substrate 11 obtained by cutting a large substrate 111 into smaller pieces (a small piece) has been described. This, however, is not an exclusive example, a method in which respective layers are laminated on a large substrate 111 and the large substrate 111 is then cut into pieces that make a plurality of display devices 100 may be employed. FIG. 8 is a plan view showing a large substrate. FIG. 9 shows a flowchart of a manufacturing process of a display device according to this embodiment, in which respective layers are formed on a large substrate, and the large substrate is then cut into pieces that make display devices. Note here that the large substrate 111 refers to a panel member which is to be cut into smaller pieces that make a plurality of insulating substrates 11, and includes a cutting area (a cutting line) C so as to correspond to the size of the frame area N of each TFT substrate 10.

Initially, the large substrate 111 is prepared (step ST11). Then, a plurality of circuit layers 12 corresponding to the number of display devices 100 which can be obtained from one large substrate 111 are formed on the large substrate 111 (step ST12). Further, a light emitting element layer 13 is formed on each circuit layer 12 in the display area M (step ST13).

Further, the sealing layer 14 is formed on the circuit layer and the light emitting element layer 13 (step ST14). Specifically, the sealing layer 14 is formed on each circuit layer 12 in the terminal area T, and on the light emitting element layer 13 in the display area M.

Thereafter, acrylic resin, or liquid resin material, is applied onto the sealing layer 14 in the display area M such that the sealing layer 14 is exposed in each terminal area T (step ST15). Further, ultraviolet light is irradiated to, to thereby cure, the acrylic resin applied to form the applied resin layer 15 (step ST16).

Further, a part of the sealing layer 14, formed in the terminal area T is removed by means of dry etching, using the applied resin layer 15 as a mask (step ST17). With the above, so called terminal exposure, or exposing the terminal 12a in the terminal area T, is implemented. As a result, the terminal 12a is available for electric connection to an electronic component etc., outside the TFT substrate 10.

Further, after the above described respective steps, the large substrate 111 is cut in the cutting area C (step ST18). With the above, a plurality of display devices 100 are obtained.

Note here that in formation of the sealing layer 14 made from inorganic material on the large substrate 111, the sealing layer 14 may be formed in the cutting area C of the large substrate 111. In this case, cutting the large substrate 111 with the sealing layer 14 formed in the cutting area C may possibly cause micro crack in the sealing layer 14 due to an impact at the time of cutting. Micro crack in the sealing layer 14 may cause invasion of water into the display device 100. To address the above, in dry etching at step ST17 to remove the sealing layer 14 in the terminal area T, the sealing layer 14 in the cutting area C may be similarly removed. Alternatively, a mask may be provided to both of the terminal area T and the cutting area C in formation of the sealing layer 14 so that the sealing layer 14 is not formed in the terminal area T and the cutting area C. However, a mask in the size corresponding to the large substrate 111 is not readily available.

Note that a glass substrate, a flexible polyimide substrate, etc., may be used as the large substrate 111. Use of a glass substrate as the large substrate 111 can facilitate and stabilize formation of respective layers and substrates. Also, when a glass substrate is used as the large substrate 111, it is preferable to add a step of removing the glass substrate after step ST19, in view of flexibility of the display device 100.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method for manufacturing a display device including a display area for image display and a terminal area around the display area with a terminal arranged therein, comprising steps of:
preparing an insulating substrate;
forming a circuit layer having the terminal on the insulating substrate;
forming a light emitting element layer on the circuit layer in the display area;
forming a sealing layer on the circuit layer in the terminal area and on the light emitting element layer in the display area;
applying resin material onto the sealing layer in the terminal area and the display area;
forming an applied resin layer so as to cover the display area and so as to expose the sealing layer in the terminal area by curing the resin material applied; and
removing apart of the sealing layer, formed in the terminal area, using the applied resin layer as a mask.

2. The method for manufacturing a display device according to claim 1, wherein
the resin material has thermosetting or UV curable property, and
at the step of forming the applied resin layer, heat or UV light is applied to the resin material to thereby cure the resin material to form the applied resin layer.

3. The method for manufacturing a display device according to claim 1, wherein at the step of removing a part of the sealing layer, formed in the terminal area, the sealing layer is removed by dry etching process.

4. The method for manufacturing a display device according to claim 3, further comprising a step of removing apart or entirety of the applied resin layer by ashing process after the sealing layer is removed by dry etching process at the step of removing the part of the sealing layer, formed in the terminal area.

5. The method for manufacturing a display device according to claim 1, wherein
respective steps up to the step of removing the part of the sealing layer, formed in the terminal area are executed with respect to a large substrate from which the insulating substrate is obtained,
at the step of removing the part of the sealing layer, formed in the terminal area, a part of the sealing layer formed in a cutting area is removed, using the applied resin layer as a mask, the cutting area being an area to be cut off to obtain a plurality of the display devices from the large substrate, and
the method further comprises a step of cutting the large substrate to obtain a plurality of the display devices after the step of removing the part of the sealing layer, formed in the terminal area.

6. A display device including a display area for image display and a terminal area around the display area with a terminal arranged therein, comprising:
a circuit layer having the terminal;
a light emitting element layer formed on the circuit layer in the display area;
a sealing layer formed on the light emitting element layer in the display area; and
an applied resin layer made from thermosetting or UV curable resin material and formed on the sealing layer in the display area.
